(19) United States
(12) Patent Application Publication
(10) Pub. No.: US 2026/0123163 A1
(43) Pub. Date: Apr. 30, 2026

(54) PACKAGE STRUCTURE

(71) Applicant: Lextar Electronics Corporation, Hsinchu City (TW)

(72) Inventor: Shiou-Yi KUO, Hsinchu City (TW)

(21) Appl. No.: 19/365,671

(22) Filed: Oct. 22, 2025

(30) Foreign Application Priority Data
Oct. 24, 2024 (TW) 113140510

(51) Int. Cl. H10H 29/85; H10H 20/851; H10H 20/856; H10H 29/24

(52) U.S. Cl. CPC H10H 29/8583; H10H 20/851; H10H 20/856; H10H 29/24; H10H 29/857; H10H 29/8582

(57) ABSTRACT

A packaging structure is provided. The packaging structure includes a dielectric structure, a redistribution structure, a plurality of light-emitting elements, a color conversion layer, and a metal barrier wall. The redistribution structure is disposed in the dielectric structure. The plurality of light-emitting elements is disposed on the dielectric structure and electrically connected to the redistribution structure. The color conversion layer is disposed on the plurality of light-emitting elements. The metal barrier wall is disposed on the dielectric structure and surrounds the color conversion layer.

### CROSS REFERENCE TO RELATED APPLICATIONS

This application claims priority of Taiwan patent application No. 113140510, filed on Oct. 24, 2024, the entirety of which is incorporated by reference herein.

### TECHNICAL FIELD

The present disclosure relates to a packaging structure, and, in particular, it relates to a packaging structure that includes a metal barrier wall.

### BACKGROUND

As electronic products become miniaturized, there are often problems such as optical cross-talk with existing packaging structures. As a result, they are limited in applications with high light-emitting quality requirements. Furthermore, adaptive headlamps with packaging structures are also limited.

Therefore, although existing packaging structures and adaptive headlamps including the same have gradually met their intended purposes, they still do not fully meet requirements in all respects. Therefore, there are still problems to be overcome regarding packaging structures and adaptive headlamps including the same.

### BRIEF SUMMARY

The packaging structure disclosed herein includes a metal barrier wall, thereby preventing optical cross-talk between adjacent light-emitting elements among a plurality of light-emitting elements, thereby improving the light-emitting quality of the packaging structure.

An embodiment of the present disclosure provides a packaging structure. The packaging structure includes a dielectric structure, a redistribution structure, a plurality of light-emitting elements, a color conversion layer, and a metal barrier wall. The redistribution structure is disposed in the dielectric structure. The plurality of light-emitting elements is disposed on the dielectric structure and electrically connects to the redistribution structure. The color conversion layer is disposed on the plurality of light-emitting elements. The metal barrier wall is disposed on the dielectric structure and surrounds the color conversion layer.

The packaging structure of the present disclosure may be applied in various types of electronic apparatus. In order to make the features and advantages of some embodiments of the present disclosure more understand, some embodiments of the present disclosure are listed below in conjunction with the accompanying drawings, and are described in detail as follows.

### BRIEF DESCRIPTION OF THE DRAWINGS

The present disclosure can be more fully understood from the following detailed description when read in conjunction with the accompanying drawings. It should be noted that, according to the standard practice in the industry, the various features are not drawn to scale. In fact, the dimensions of the various features may be arbitrarily increased or reduced for clarity.

FIG. 1 is a schematic cross-sectional view of a packaging structure 1 according to some embodiments of the present disclosure.

FIG. 2 is a partial schematic view of a first region R1 according to some embodiments of the present disclosure.

FIG. 3 is a partial schematic view of a second region R2 according to some embodiments of the present disclosure.

FIG. 4 to FIG. 20 are schematic cross-sectional views of different stages of a method for forming a packaging structure according to some embodiments of the present disclosure.

FIG. 21 is a schematic cross-sectional view of a packaging structure 2 according to some embodiments of the present disclosure.

### DETAILED DESCRIPTION

Packaging structures and adaptive headlamps of various embodiments of the present disclosure will be described in detail below. It should be understood that the following description provides many different embodiments for implementing various aspects of some embodiments of the present disclosure. The specific elements and arrangements described below are merely to clearly describe some embodiments of the present disclosure. Of course, these are only used as examples rather than limitations of the present disclosure. Furthermore, similar or corresponding reference numerals may be used in different embodiments to designate similar or corresponding elements in order to clearly describe the present disclosure. However, the use of these similar or corresponding reference numerals is only for the purpose of simply and clearly description of some embodiments of the present disclosure, and does not imply any correlation between the different embodiments or structures discussed.

It should be understood that relative terms, such as “lower”, “bottom”, “higher”, or “top” may be used in various embodiments to describe the relative relationship of one element of the drawings to another element. It will be understood that if the device in the drawings were turned upside down, elements described on the “lower” side would become elements on the “upper” side. The embodiments of the present disclosure can be understood together with the drawings, and the drawings of the present disclosure are also regarded as a portion of the disclosure. Furthermore, when it is mentioned that a first material layer is located on or over a second material layer, it may include the embodiment which the first material layer and the second material layer are in direct contact and the embodiment which the first material layer and the second material layer are not in direct contact with each other, that is one or more layers of other materials is between the first material layer and the second material layer. However, if the first material layer is directly on the second material layer, it means that the first material layer and the second material layer are in direct contact. In addition, it should be understood that ordinal numbers such as “first”, “second”, and the like used in the description and claims are used to modify elements and are not intended to imply and represent the element(s) have any previous ordinal numbers, and do not represent the order of a certain element and another element, or the order of the manufacturing method, and the use of these ordinal numbers is only used to clearly distinguished an element with a certain name and another element with the same name. The claims and the specification may not use the same terms, for example, a first element in the specification may be a second element in the claim.

Herein, the terms “approximately”, “about”, and “substantially” generally mean within 10%, within 5%, within 3%, within 2%, within 1%, or within 0.5% of a given value or range. The given value is an approximate value, that is, “approximately”, “about”, and “substantially” can still be implied without the specific description of “approximately”, “about”, and “substantially”. The phrase “a range between a first value and a second value” means that the range includes the first value, the second value, and other values in between. Furthermore, any two values or directions used for comparison may have certain tolerance. If the first value is equal to the second value, it implies that there may be a tolerance within about 10%, within 5%, within 3%, within 2%, within 1%, or within 0.5% between the first value and the second value. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

Herein, the respective directions are not limited to three axes of the rectangular coordinate system, such as the X-axis, the Y-axis, and the Z-axis, and may be interpreted in a broader sense. For example, the X-axis, the Y-axis, and the Z-axis may be perpendicular to each other, or may represent different directions that are not perpendicular to each other, but the present disclosure is not limited thereto. For convenience of description, hereinafter, the X-axis direction is the first direction D1 (width direction), the Y-axis direction is the second direction D2 (length direction), and the Z-axis direction is the third direction D3 (thickness/depth direction). In some embodiments, the schematic cross-sectional views described herein are schematic views of the XZ plane. In some embodiments, the third direction D3 may be a normal direction of the light-emitting elements 20.

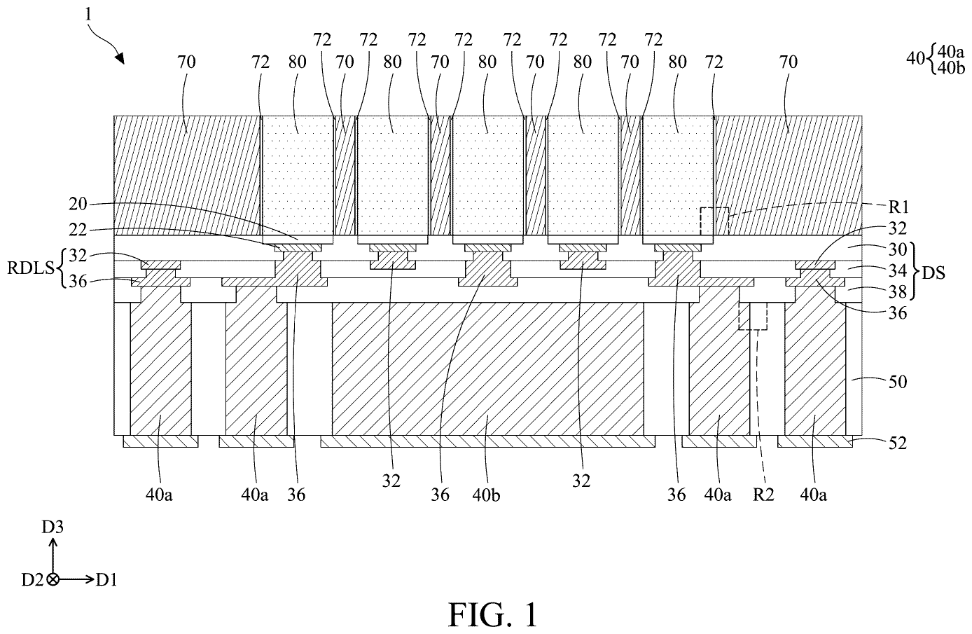

Referring to FIG. 1, it is a cross-sectional view of a packaging structure 1 according to some embodiments of the present disclosure. As shown in FIG. 1, in some embodiments, the packaging structure 1 may include a dielectric structure DS, a redistribution structure RDLS, a plurality of light-emitting elements 20, a color conversion layer 80, and a metal barrier wall 70.

As shown in FIG. 1, in some embodiments, the dielectric structure DS may include one or more dielectric layers. In some embodiments, the dielectric layer may include an oxide such as silicon oxide, a nitride such as silicon nitride, an oxynitride such as silicon oxynitride, the like, or a combination thereof, but the present disclosure is not limited thereto. In some embodiments, the dielectric layer may include epoxy, polyimide (PI), polybenzoxazole (PBO), silicone. In some embodiments, the dielectric structure DS may include 1 to 100 dielectric layers, but the present disclosure is not limited thereto. For example, the number of dielectric layers may be 1, 2, 3, 4, 5, 10, 20, 30, 40, 50, 60, 70, 80, 90, 100, or any value or any range of values between the aforementioned values, but the present disclosure is not limited thereto. For ease of illustration, FIG. 1 shows that the dielectric structure DS may include three dielectric layers. For example, the dielectric structure DS may include a first dielectric layer 30, a second dielectric layer 34, and a third dielectric layer 38 stacked in sequence.

As shown in FIG. 1, in some embodiments, the redistribution structure RDLS may be disposed in the dielectric structure DS. In some embodiments, the redistribution structure RDLS may include one or more redistribution layers. In some embodiments, the redistribution layers may include a conductive material. In some embodiments, the aforementioned conductive material may include a metal, a conductive metal oxide, a conductive metal nitride, the like, or a combination thereof, but the present disclosure is not limited thereto. For example, the metal may include tin (Sn), copper (Cu), gold (Au), silver (Ag), nickel (Ni), indium (In), platinum (Pt), palladium (Pd), iridium (Ir), titanium (Ti), chromium (Cr), tungsten (W), aluminum (Al), molybdenum (Mo), titanium (Ti), magnesium (Mg), zinc (Zn), alloys thereof or compounds thereof, or a combination thereof, but the present disclosure is not limited thereto. For example, the conductive metal oxide may be a transparent conductive oxide (TCO). For example, the transparent conductive oxide may include indium tin oxide (ITO), antimony zinc oxide (AZO), tin oxide (SnO), zinc oxide (ZnO), indium zinc oxide (IZO), indium gallium zinc oxide (IGZO), indium tin zinc oxide (ITZO), antimony tin oxide (ATO), the like, or a combination thereof, but the present disclosure is not limited thereto. For example, the conductive metal nitride may include TiN, WN, TaN, the like, or a combination thereof, but the present disclosure is not limited thereto.

In some embodiments, the redistribution structure RDLS may include 1 to 100 redistribution layers, but the present disclosure is not limited thereto. For example, the number of redistribution layers may be 1, 2, 3, 4, 5, 10, 20, 30, 40, 50, 60, 70, 80, 90, 100, or any value or any range of values between the aforementioned values, but the present disclosure is not limited thereto. For ease of explanation, FIG. 1 shows that the redistribution structure RDLS may include two redistribution layers. For example, the redistribution structure RDLS may include a first redistribution layer 32 and a second redistribution layer 36 stacked in sequence. In some embodiments, the redistribution layers of the redistribution structure RDLS may be stacked alternately with the dielectric layers of the dielectric structure DS. Wherein, the dielectric layers of the dielectric structure DS may serve as insulating layers between the redistribution layers of the redistribution structure RDLS.

As shown in FIG. 1, in some embodiments, the plurality of light-emitting elements 20 may be disposed on the dielectric structure DS. In some embodiments, the plurality of light-emitting elements 20 may be electrically connected to the redistribution structure RDLS. In some embodiments, the light-emitting elements 20 may be arranged at intervals from each other. In some embodiments, in a top view, the plurality of light-emitting elements 20 may be arranged in an array. In some embodiments, the light-emitting element 20 may be a light-emitting diode (LED), a mini light-emitting diode (mini LED), a micro light-emitting diode (micro LED), the like, or a combination thereof, but the present disclosure is not limited thereto. In some embodiments, the light-emitting element 20 may emit red light, green light, blue light, ultraviolet light (UV light), or other light of suitable wavelength.

In some embodiments, the light-emitting element 20 may include a substrate (not shown), a semiconductor stack (not shown), an insulating layer (not shown), a functional layer such as a reflective layer (not shown), and a bonding pad 22. In some embodiments, the semiconductor stack may include a first semiconductor layer (not shown), a light-emitting layer (not shown), and a second semiconductor layer (not shown) stacked in sequence, and the first semiconductor layer and the second semiconductor layer have different conductivity types. In some embodiments, the bonding pad 22 may be electrically connected to the semiconductor stack. In some embodiments, the bonding pad 22 may include the aforementioned conductive material. In some embodiments, the light-emitting element 20 may be electrically connected to the redistribution structure RDLS via the bonding pad 22. In some embodiments, the light-emitting element 20 may be flip-chip type. In some embodiments, the light-emitting element 20 does not have a substrate. For example, the light-emitting element 20 does not have an epitaxial substrate of a patterned sapphire substrate (PSS). That is, the light-emitting element 20 includes a semiconductor stack but does not include a patterned sapphire substrate on which the semiconductor stack is grown. The light-emitting surface of the light-emitting element 20 has a periodically arranged concave-convex pattern produced by performing a laser lift-off process on the patterned sapphire substrate.

In some embodiments, the number of light-emitting elements 20 in the packaging structure 1 may be 1 to 10,000. For example, the number of light-emitting elements 20 may be 1, 2, 3, 4, 5, 25, 100, 2,500, 10,000, or any value or any range of values between the aforementioned values, but the present disclosure is not limited thereto. In some embodiments, the number of light-emitting elements 20 in the packaging structure 1 may be n×m, where n may be a positive integer from 1 to 100, and m may be a positive integer from 1 to 100. In this embodiment, the light-emitting elements 20 may be arranged in an array of n columns and m rows. For ease of explanation, in the schematic cross-sectional view shown in FIG. 1, five light-emitting elements 20 are shown, but the present disclosure is not limited thereto.

As shown in FIG. 1, in some embodiments, the color conversion layer 80 may be disposed on each of the light-emitting elements 20 to convert the color (that is, wavelength) of the light emitted from each of the light-emitting elements 20. In some embodiments, the width of the color conversion layer 80 may be substantially equal to the width of the light-emitting element 20. In some embodiments, the projection range of the light-emitting element 20 on the first dielectric layer 30 may be located within or completely overlapped with the projection range of the color conversion layer 80 on the first dielectric layer 30. In some embodiments, the color conversion layer 80 may be formed by a dispensing process, a deposition process, another suitable process, or a combination thereof, but the present disclosure is not limited thereto. In some embodiments, the color conversion layer 80 may be used to convert a light having a first wavelength emitted by the light-emitting element 20 into a light having a second wavelength, wherein the first wavelength is different from the second wavelength.

In some embodiments, the color conversion layer 80 may include a color conversion matrix and a wavelength conversion material dispersed in the color conversion matrix. In some embodiments, the color conversion matrix may include a transparent resin. For example, the color conversion matrix may include an acrylate-based resin, an organosiloxane-based resin, an acrylate-modified polyurethane, an acrylate-modified organosilicon-based resin, an epoxy resin, the like, or a combination thereof, but the present disclosure is not limited thereto.

In some embodiments, the wavelength conversion material may include a red light conversion material, a blue light conversion material, a green light conversion material, a yellow light conversion material, another suitable light conversion material, or a combination thereof. In some embodiments, the red light conversion material may include red quantum dots or red phosphors, but the present disclosure is not limited thereto. For example, the red light conversion material may include (Sr, Ca)AlSiN₃:Eu²⁺, Ca₂Si₅N₈:Eu²⁺, Sr(LiAl₃N₄):Eu²⁺, manganese-doped red fluoride phosphors, the like, or a combination thereof, but the present disclosure is not limited thereto. The manganese-doped red fluoride phosphors may include K₂GeF₆:Mn⁴⁺, K₂SiF₆:Mn⁴⁺, K₂TiF₆:Mn⁴⁺, the like, or a combination thereof, but the present disclosure is not limited thereto. In some embodiments, the blue light conversion material may include blue quantum dots or blue phosphors, but the present disclosure is not limited thereto. In some embodiments, the green light conversion material may include green quantum dots or green phosphors, but the present disclosure is not limited thereto. For example, the green light conversion material may include lutetium aluminium garnet (LuAG) phosphors, yttrium aluminum garnet (YAG) phosphors, sialon (β-SiAlON) phosphors, silicate phosphors, the like, or a combination thereof, but the present disclosure is not limited thereto. In some embodiments, the yellow light conversion material may include yellow quantum dots or yellow phosphors. For example, the yellow light conversion material may include yttrium aluminum garnet (YAG) phosphors.

In some embodiments, the light-emitting element 20 may emit blue light, and the color conversion layer 80 may include a yellow light conversion material. For example, the yellow light conversion material may be yttrium aluminum garnet (YAG) phosphor. Therefore, the light emitted by the light-emitting element 20 may be white light after passing through the color conversion layer 80. In some embodiments, the light-emitting element 20 may emit blue light, and the color conversion layer 80 may include a combination of the green light conversion material and the red light conversion material. For example, the color conversion layer 80 may include a green β-SiAlON phosphor and a red K₂SiF₆:Mn⁴⁺ phosphor. Therefore, the light emitted by the light-emitting element 20 may be white light after passing through the color conversion layer 80. In some embodiments, the color conversion layer 80 may include a combination of one green phosphor and two red phosphors, for example, the color conversion layer 80 may include a green β-SiAlON phosphor, a red K₂SiF₆:Mn⁴⁺ phosphor and a red (Sr,Ca)AlSiN₃:Eu²⁺ phosphor. In some embodiments, the color conversion layer 80 may include red quantum dots and green quantum dots. In some embodiments, the color conversion layer 80 may include a red quantum dot film and a green quantum dot film.

In some embodiments, the color conversion layer 80 may further include diffusion particles dispersed in the color conversion matrix. In some embodiments, the diffusion particles may include inorganic particles, organic polymer particles, or a combination thereof. For example, the inorganic particles may include silicon oxide, titanium oxide, aluminum oxide, calcium carbonate, barium sulfate, or any combination thereof, but the present disclosure is not limited thereto. For example, the organic polymer particles may include polymethyl methacrylate (PMMA), polystyrene (PS), acrylonitrile-butadiene-styrene copolymer (ABS), polyurethane (PU), or any combination thereof, but the present disclosure is not limited thereto.

As shown in FIG. 1, in some embodiments, the metal barrier wall 70 may be disposed on the dielectric structure DS. In some embodiments, the metal barrier wall 70 may surround the color conversion layer 80. In some embodiments, the metal barrier wall 70 may cover at least one side surface or all side surfaces of the color conversion layer 80. In some embodiments, the metal barrier wall 70 may include a metal. For example, the metal may include tin, copper, gold, silver, nickel, indium, platinum, palladium, iridium, titanium, chromium, tungsten, aluminum, molybdenum, titanium, magnesium, zinc, alloys thereof, compounds thereof, or a combination thereof, but the present disclosure is not limited thereto. In some embodiments, the metal barrier wall 70 may include copper.

As shown in FIG. 1, in some embodiments, the packaging structure 1 may include a reflective layer 72. In some embodiments, the reflective layer 72 may be disposed on the dielectric structure DS. In some embodiments, the reflective layer 72 may be disposed between the color conversion layer 80 and the metal barrier wall 70. In some embodiments, the reflective layer 72 may surround the color conversion layer 80, and the metal barrier wall 70 may surround the reflective layer 72. In some embodiments, the reflective layer 72 may include a reflective material. For example, the reflective material may include metal, white paint, white photoresist, the like, or a combination thereof, but the present disclosure is not limited thereto. For example, the metal may include tin, copper, gold, silver, nickel, indium, platinum, palladium, iridium, titanium, chromium, tungsten, aluminum, molybdenum, titanium, magnesium, zinc, alloys thereof, compounds thereof, or a combination thereof, but the present disclosure is not limited thereto. In some embodiments, the reflective material of the reflective layer 72 may have a reflectivity greater than or equal to 80% at a wavelength of visible light. For example, the reflectivity of the reflective material at the wavelength of visible light may be 80%, 85%, 90%, 95%, 99%, 99.9%, or any value or any range of values between the aforementioned values, but the present disclosure is not limited thereto.

As shown in FIG. 1, in some embodiments, the packaging structure 1 may include a packaging layer 50 and a pillar structure 40. In some embodiments, the packaging layer 50 and the pillar structure 40 may be used together to carry and support the plurality of light-emitting elements 20. In some embodiments, the dielectric structure DS may be disposed between the packaging layer 50 and the metal barrier wall 70. In some embodiments, the metal barrier wall 70 may be disposed on the top surface of the dielectric structure DS, and the packaging layer 50 may be disposed on the bottom surface of the dielectric structure DS. In other words, the metal barrier wall 70 and the packaging layer 50 may be disposed on opposite surfaces of the dielectric structure DS. In some embodiments, the packaging layer 50 may include a molding material. For example, the molding material may include epoxy, silicone, the like, or a combination thereof, but the present disclosure is not limited thereto. For example, the molding material may include a solid molding material (for example, epoxy molding compound (EMC)). The solid molding material may include epoxy, phenolic resin, silicon dioxide, or other suitable materials, but the present disclosure is not limited thereto. The packaging layer 50 may include the molding material and diffusion particles (filler). In some embodiments, the diffusion particles include titanium dioxide (TiO₂), silicon dioxide (SiO₂), boron oxide (BN), aluminum oxide (Al₂O₃), or zirconium dioxide (ZrO₂). In some embodiments, the diffusion particles include hollow silicon dioxide (SiO₂) or solid silicon dioxide (SiO₂). In some embodiments, the packaging layer 50 may include diffusion particles with two or more different sizes. For example, the packaging layer 50 includes diffusion particles with two different sizes, three different sizes, four different sizes, or five different sizes, or more. In some embodiments, the diffusion particles may be spherical or elongated. In some embodiments, the packaging layer 50 may include spherical diffusion particles with two or more different radii.

In some embodiments, the metal barrier wall 70 may be in contact with the first dielectric layer 30. In some embodiments, the packaging layer 50 may be in contact with the third dielectric layer 38. In some embodiments, the second dielectric layer 34 may be disposed between the first dielectric layer 30 and the third dielectric layer 38. In some embodiments, the first redistribution layer 32 may be disposed between the first dielectric layer 30 and the second dielectric layer 34. In some embodiments, the second redistribution layer 36 may be disposed on the first redistribution layer 32 to electrically connect the plurality of light-emitting elements 20.

In some embodiments, the pillar structure 40 may be disposed in the packaging layer 50. In some embodiments, the packaging layer 50 may surround at least one side surface or all side surfaces of the pillar structure 40. In some embodiments, the pillar structure 40 may include the aforementioned conductive material. In some embodiments, the material of the pillar structure 40 may be the same as the material of the metal barrier wall 70. In other embodiments, the material of the pillar structure 40 may be different from the material of the metal barrier wall 70. In some embodiments, the thermal conductivity of the pillar structure 40 may be the same as the thermal conductivity of the metal barrier wall 70. In some embodiments, the pillar structure 40 may include copper (Cu), and the metal barrier wall 70 may include copper (Cu). Accordingly, when the material of the pillar structure 40 may be the same as the material of the metal barrier wall 70, or the thermal conductivity of the pillar structure 40 may be the same as the thermal conductivity of the metal barrier wall 70, the thermal conductivity efficiency, heat dissipation distribution uniformity, and/or reliability of the packaging structure 1 may be improved.

In some embodiments, the pillar structure 40 may include a plurality of conductive pillars 40a and a heat dissipation pillar 40b. In some embodiments, the conductive pillars 40a and the heat dissipation pillar 40b of the pillar structure 40 may be physically separated from each other. In other words, a distance may be spaced between the conductive pillar 40a and the heat dissipation pillar 40b of the pillar structure 40. In some embodiments, each of the conductive pillars 40a may be electrically connected to the redistribution structure RDLS and the plurality of light-emitting elements 20. In some embodiments, each of the conductive pillars 40a of the pillar structure 40 may pass through the third dielectric layer 38 and be electrically connected to the second redistribution layer 36. Therefore, each of the conductive pillars 40a may be used to electrically connect the light-emitting elements 20 to other elements.

In some embodiments, the heat dissipation pillar 40b may be electrically isolated from the redistribution structure RDLS and the plurality of light-emitting elements 20. In some embodiments, the heat dissipation pillar 40b of the pillar structure 40 may be disposed on the top surface of the third dielectric layer 38 and does not pass through the third dielectric layer 38. In some embodiments, the heat dissipation pillar 40b of the pillar structure 40 may be physically separated from the second redistribution layer 36. In other words, the heat dissipation pillar 40b of the pillar structure 40 may be spaced a distance from the second redistribution layer 36. Therefore, the heat dissipation pillar 40b may be used to dissipate heat energy.

In some embodiments, the heat dissipation pillar 40b may be located below at least one of the plurality of light-emitting elements 20. In some embodiments, the projection range of at least one of the plurality of light-emitting elements (for example, a single light-emitting element) 20 on the first dielectric layer 30 may be located within the projection range of the heat dissipation pillar 40b on the first dielectric layer 30. Accordingly, since the heat dissipation pillar 40b may be disposed adjacent to the plurality of light-emitting elements 20, the heat dissipation effect for the plurality of light-emitting elements 20 may be improved to improve the light-emitting quality, light-emitting stability, and/or reliability of the light-emitting elements 20. In some embodiments, the plurality of conductive pillars 40a may surround the heat dissipation pillar 40b. Accordingly, the conductive pillars 40a may improve the disposing margin (window) of the conductive path of the packaging structure 1. Therefore, the pillar structure 40 may provide both electrical connection function and heat dissipation function.

As shown in FIG. 1, in some embodiments, the packaging structure 1 may include a plurality of bonding pads 52. In some embodiments, each of the bonding pads 52 may be electrically connected to the pillar structure 40. In some embodiments, the bonding pads 52 may cover the bottom surface of the pillar structure 40. In some embodiments, the material of the bonding pads 52 may be the same as or different from the material of the pillar structure 40. In some embodiments, the bonding pads 52 may include the aforementioned conductive material. Wherein, the bonding pads 52 electrically connected to the conductive pillars 40a of the pillar structure 40 provide electrical connection function of electrically connected to an external element. The bonding pads 52 connected to the heat dissipation pillar 40b of the pillar structure 40 provide heat dissipation function to improve the heat dissipation efficiency of the heat dissipation element including the heat dissipation pillar 40b and the bonding pad 52.

Accordingly, the redistribution structure RDLS, the conductive pillar 40a, and the bonding pads 52 in the packaging structure 1 may be used together as an extended electrode of the light-emitting element 20 to improve the light-emitting efficiency, improve the bonding reliability, and/or avoid electrical failure. In detail, the alignment during bonding processes such as fusion bonding is difficult and leads to reduced light-emitting efficiency, insufficient bonding reliability, and even electrical failure of the light-emitting element 20. In addition, since bonding processes such as fusion bonding require precise alignment, the process margin of the forming process is also limited. Therefore, based on the present disclosure, the use of the redistribution structure RDLS, the conductive pillar 40a, and the bonding pads 52 as the extended electrode of the packaging structure 1 may effectively avoid the above-mentioned problems existing in the pad-to-pad (point-to-point) bonding structure.

In some embodiments, in a top view (not shown), the metal barrier wall 70 may be in a mesh shape. For example, in a top view (not shown), the metal barrier wall 70 may include a plurality of frames arranged in an array. In other words, the six metal barrier walls 70 shown in FIG. 1 may be physically connected to each other. In some embodiments, in a top view (not shown), the conductive pillar 40a and the heat dissipation pillar 40b in the pillar structure 40 are physically separated from each other.

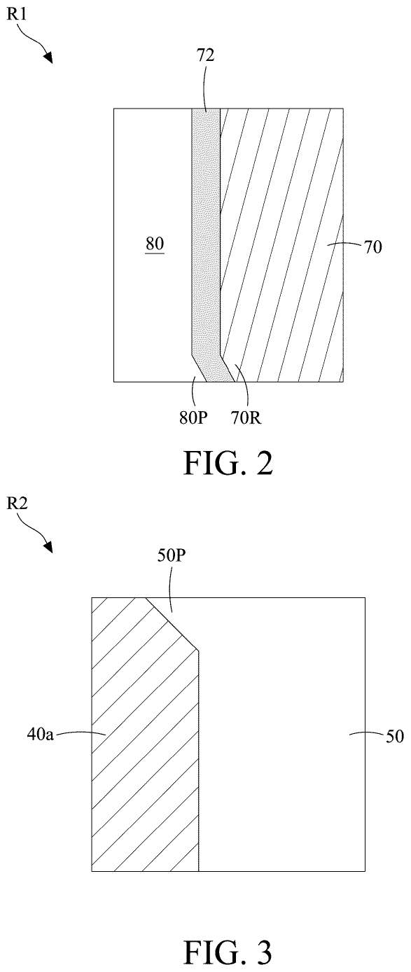

Referring to FIG. 2, it is a partial schematic view of a first region R1 of some embodiments of the present disclosure. FIG. 2 shows a schematic view of the first region R1 of the packaging structure 1 shown in FIG. 1. As shown in FIG. 2, in some embodiments, a bottom end portion 80P of the color conversion layer 80 may protrude toward the metal barrier wall 70. In some embodiments, the metal barrier wall 70 may have a bottom recess 70R corresponding to the color conversion layer 80. In some embodiments, the reflective layer 72 may be conformably formed on the bottom recess 70R of the metal barrier wall 70, so that the reflective layer 72 may be between the bottom end portion 80P of the color conversion layer 80 and the bottom recess 70R of the metal barrier wall 70.

Referring to FIG. 3, it is a partial schematic view of a second region R2 of some embodiments of the present disclosure. FIG. 3 shows a schematic view of the second region R2 of the packaging structure 1 shown in FIG. 1. As shown in FIG. 3, in some embodiments, a top end portion 50P of the packaging layer 50 may protrude toward the conductive pillar 40a of the pillar structure 40. In some embodiments, the conductive pillar 40a may have a recess corresponding to the packaging layer 50. In some embodiments, the top end portion 50P of the packaging layer 50 may also protrude toward the heat dissipation pillar 40b of the pillar structure 40. In some embodiments, the heat dissipation pillar 40b may also have a recess corresponding to the packaging layer 50.

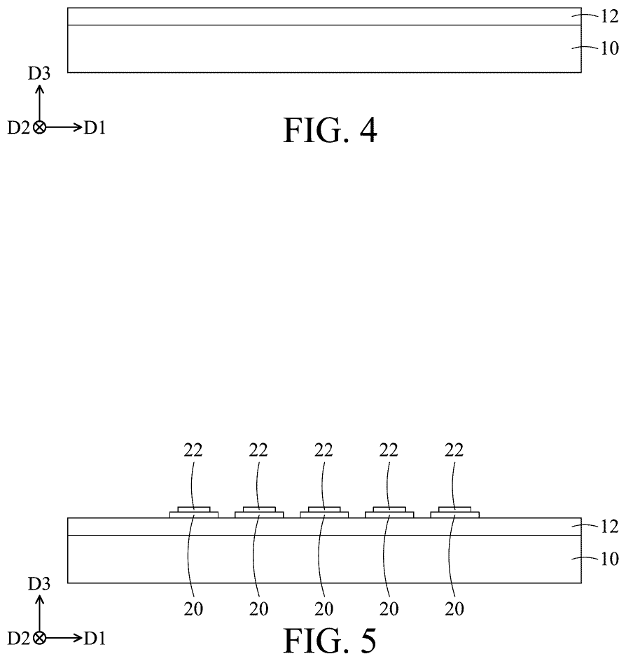

Referring FIGS. 4 to 20, they are schematic cross-sectional views of different stages of a method for forming a packaging structure according to some embodiments of the present disclosure.

As shown in FIG. 4, in some embodiments, a substrate 10 may be provided, and a first adhesive layer 12 may be formed on the substrate 10. In some embodiments, the substrate 10 may include silicon, glass, sapphire, ceramic, another suitable substrate, or a combination thereof, but the present disclosure is not limited thereto. In some embodiments, the substrate 10 may include polyimide (PI), polycarbonate (PC), polyethylene terephthalate (PET), polypropylene (PP), another suitable substrate, or a combination thereof, but the present disclosure is not limited thereto. In some embodiments, the first adhesive layer 12 may be used as a separation layer or a release layer. In some embodiments, the first adhesive layer 12 may include ultraviolet (UV) glue, thermally decomposed glue, light-to-heat conversion (LTHC) glue, another suitable adhesive material, or a combination thereof, but the present disclosure is not limited thereto. In some embodiments, the first adhesive layer 12 may be formed by a coating process, another suitable forming process, or a combination thereof, but the present disclosure is not limited thereto.

As shown in FIG. 5, in some embodiments, a plurality of light-emitting elements 20 may be formed on the first adhesive layer 12. In some embodiments, the bottom surfaces of the light-emitting elements 20 may be in contact with the first adhesive layer 12, and the bonding pads 22 of the light-emitting elements 20 are exposed.

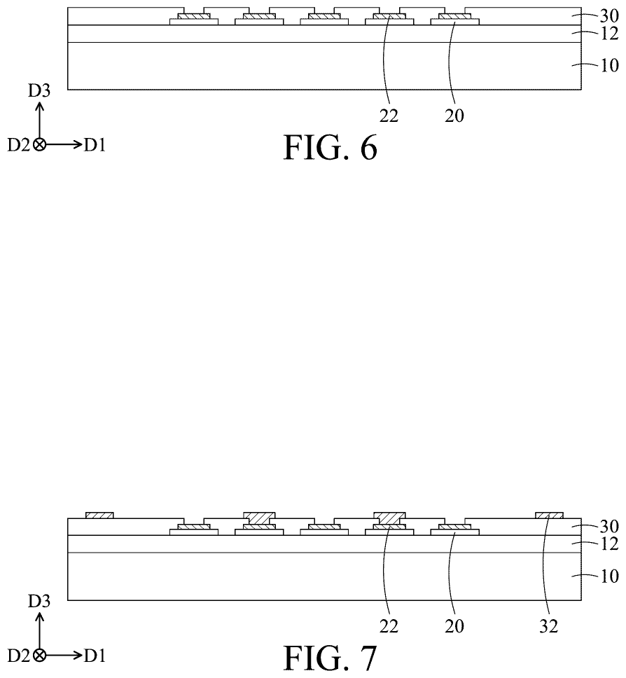

As shown in FIG. 6, in some embodiments, a first dielectric layer 30 may be formed on the plurality of light-emitting elements 20 and the first adhesive layer 12. In some embodiments, the first dielectric layer 30 may expose the bonding pads 22 of the light-emitting elements 20. In some embodiments, the first dielectric layer 30 may be formed by chemical vapor deposition, another suitable forming process, or a combination thereof, but the present disclosure is not limited thereto.

As shown in FIG. 7, in some embodiments, a first redistribution layer 32 may be formed on the first dielectric layer 30 and the bonding pads 22 of the light-emitting elements 20. In some embodiments, the first redistribution layer 32 may be formed by electroplating, chemical vapor deposition, sputtering, atomic layer deposition, another suitable forming process, or a combination thereof, but the present disclosure is not limited thereto.

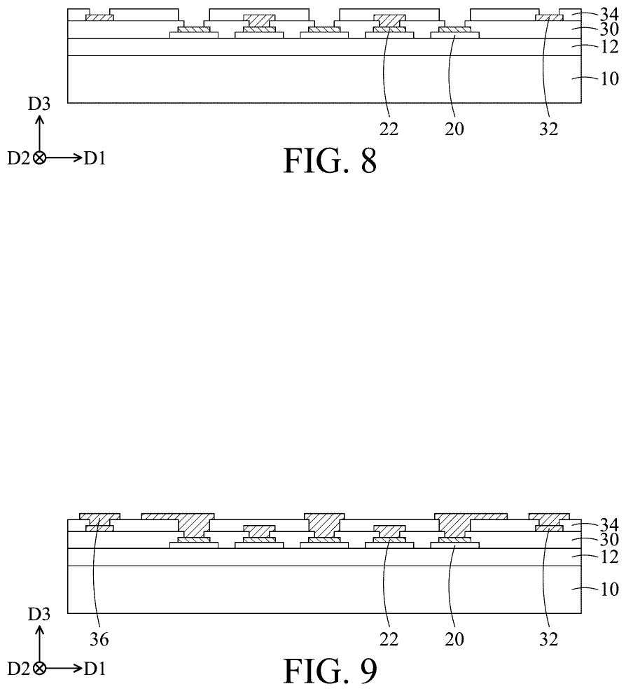

As shown in FIG. 8, in some embodiments, a second dielectric layer 34 may be formed on the first redistribution layer 32 and the first dielectric layer 30. In some embodiments, the second dielectric layer 34 may expose the bonding pads 22 of the light-emitting elements 20. In some embodiments, the formation method of the second dielectric layer 34 may be the same as or different from the formation method of the first dielectric layer 30.

As shown in FIG. 9, in some embodiments, a second redistribution layer 36 may be formed on the second dielectric layer 34, the first redistribution layer 32, and the bonding pads 22 of the light-emitting elements 20. In some embodiments, the formation method of the second redistribution layer 36 may be the same as or different from the formation method of the first redistribution layer 32.

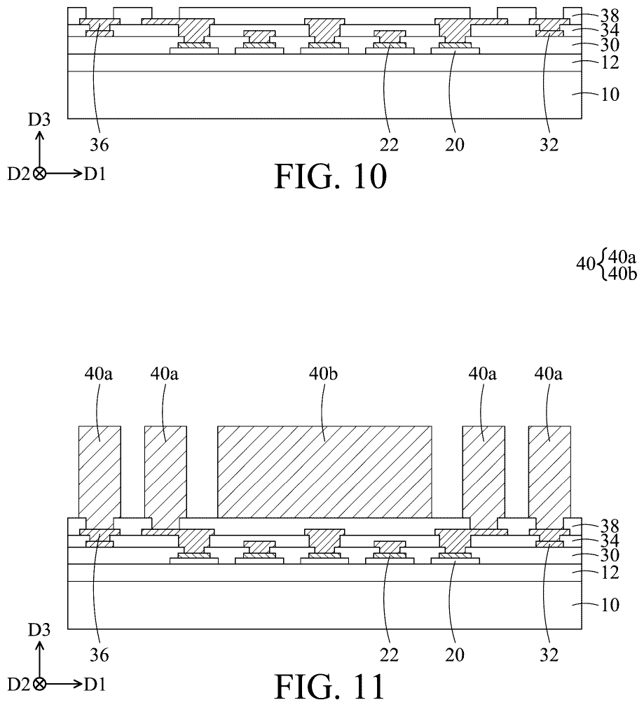

As shown in FIG. 10, in some embodiments, a third dielectric layer 38 may be formed on the second redistribution layer 36 and the second dielectric layer 34. In some embodiments, the third dielectric layer 38 may expose the second redistribution layer 36. In some embodiments, the formation method of the third dielectric layer 38 may be the same as or different from the formation method of the first dielectric layer 30.

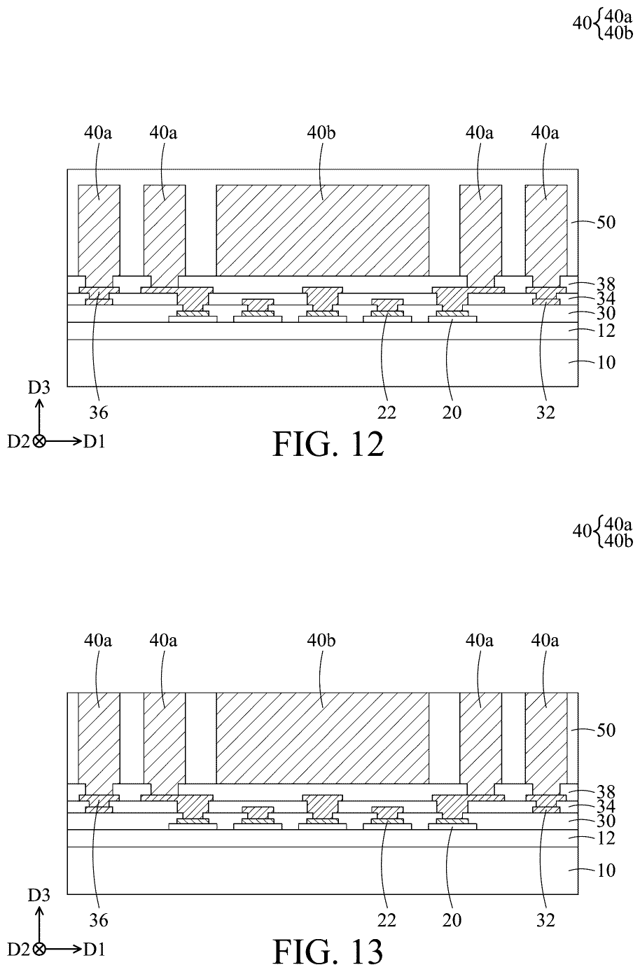

As shown in FIG. 11, in some embodiments, a pillar structure 40 may be formed on the third dielectric layer 38 and the second redistribution layer 36. In some embodiments, the pillar structure 40 may be formed by electroplating, chemical vapor deposition, sputtering, atomic layer deposition, another suitable forming process, or a combination thereof, but the present disclosure is not limited thereto. For example, the pillar structure 40 may be formed by electroplating. In some embodiments, the pillar structure 40 may include a plurality of conductive pillars 40a and a heat dissipation pillar 40b. The plurality of conductive pillars 40a and the heat dissipating pillar 40b may be formed in the same process or may be formed in different processes. In some embodiments, in a top view, the pillar structure 40 may have an array shape.

As shown in FIG. 12, in some embodiments, a packaging layer 50 may be formed on the pillar structure 40 and the third dielectric layer 38. In some embodiments, the packaging layer 50 may cover the top surface and the side surface of the pillar structure 40 and the top surface of the third dielectric layer 38. In some embodiments, the formation method of the packaging layer 50 may be the same as or different from the formation method of the first dielectric layer 30.

As shown in FIG. 13, in some embodiments, a removal process may be performed to make the top surface of the packaging layer 50 to be flush with the top surface of the pillar structure 40. In some embodiments, the removal process may include a chemical mechanical polishing process, another suitable removal process, or a combination thereof, but the present disclosure is not limited thereto.

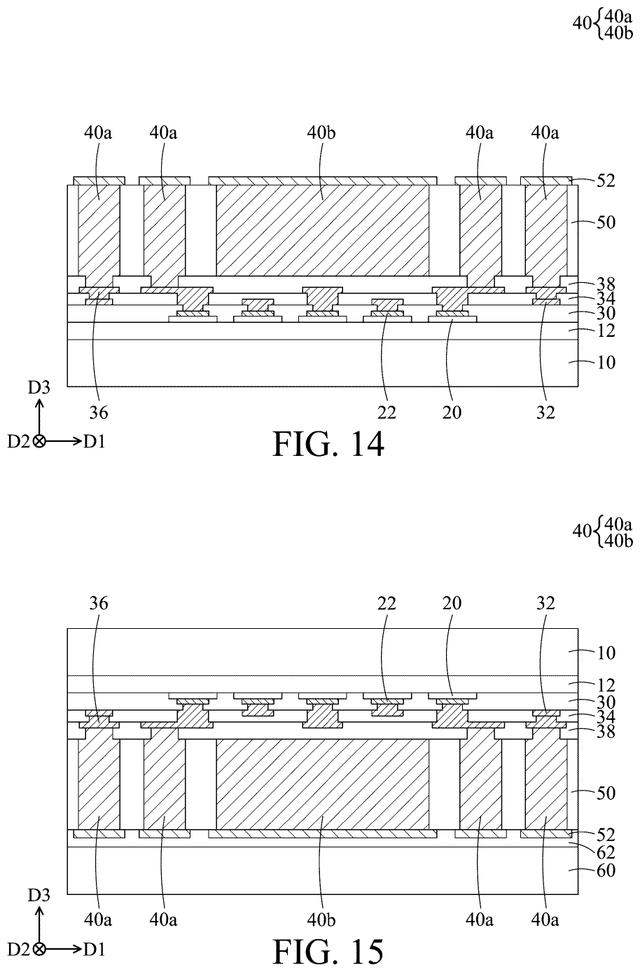

As shown in FIG. 14, in some embodiments, a plurality of bonding pads 52 may be formed on the pillar structure 40. In some embodiments, the bonding pad 52 may be formed by electroplating, chemical vapor deposition, sputtering, atomic layer deposition, another suitable forming process, or a combination thereof, but the present disclosure is not limited thereto. In some embodiments, the width of the bonding pad 52 may be greater than the pillar width of the pillar structure 40.

As shown in FIG. 15, in some embodiments, a carrier 60 may be provided, and a second adhesive layer 62 may be formed on the carrier 60. In some embodiments, the material of the carrier 60 may be the same as or different from the material of the substrate 10. In some embodiments, the material of the first adhesive layer 12 may be the same as or different from the material of the second adhesive layer 62. In some embodiments, the bonding pad 52 and the carrier 60 may be bonded by the second adhesive layer 62. Then, the structure may be turned upside down to obtain the structure shown in FIG. 15.

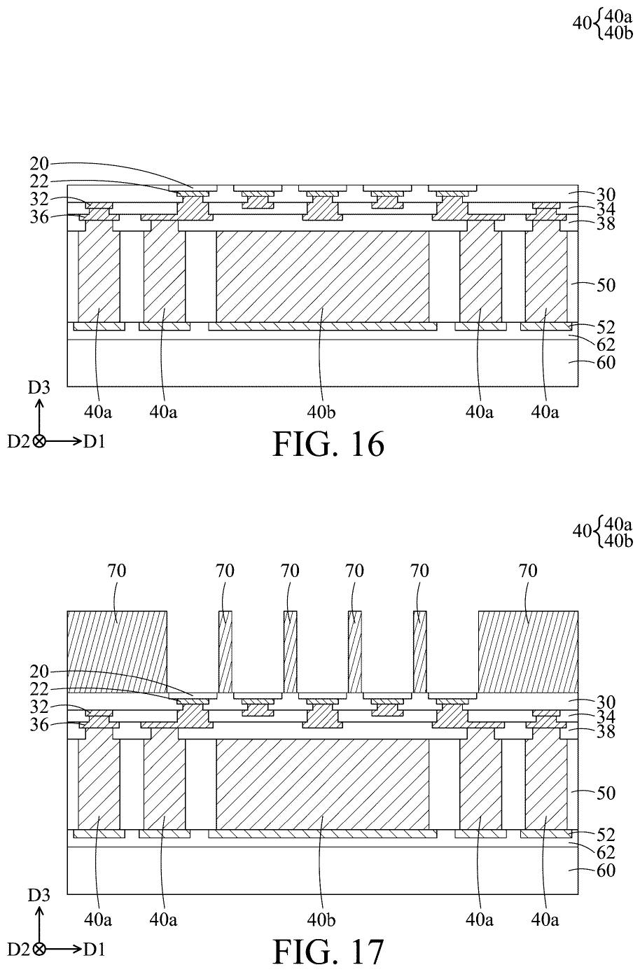

As shown in FIG. 16, in some embodiments, the substrate 10 and the first adhesive layer 12 may be removed. In some embodiments, the substrate 10 and the first adhesive layer 12 may be removed by a removal process corresponding to the first adhesive layer 12. For example, when the first adhesive layer 12 may be an ultraviolet light-removable adhesive, the removal process may include irradiating ultraviolet light.

As shown in FIG. 17, in some embodiments, a metal barrier wall 70 may be formed on the first dielectric layer 30. In some embodiments, the metal barrier wall 70 may be formed by electroplating, chemical vapor deposition, sputtering, atomic layer deposition, another suitable forming process, or a combination thereof, but the present disclosure is not limited thereto. For example, the metal barrier wall 70 may be formed on the surface of the first dielectric layer 30 where the light-emitting element 20 is not disposed by masking. In some embodiments, the metal barrier wall 70 may expose the light-emitting element 20. In some embodiments, in the third direction D3, the metal barrier wall 70 may not overlap with the light-emitting element 20.

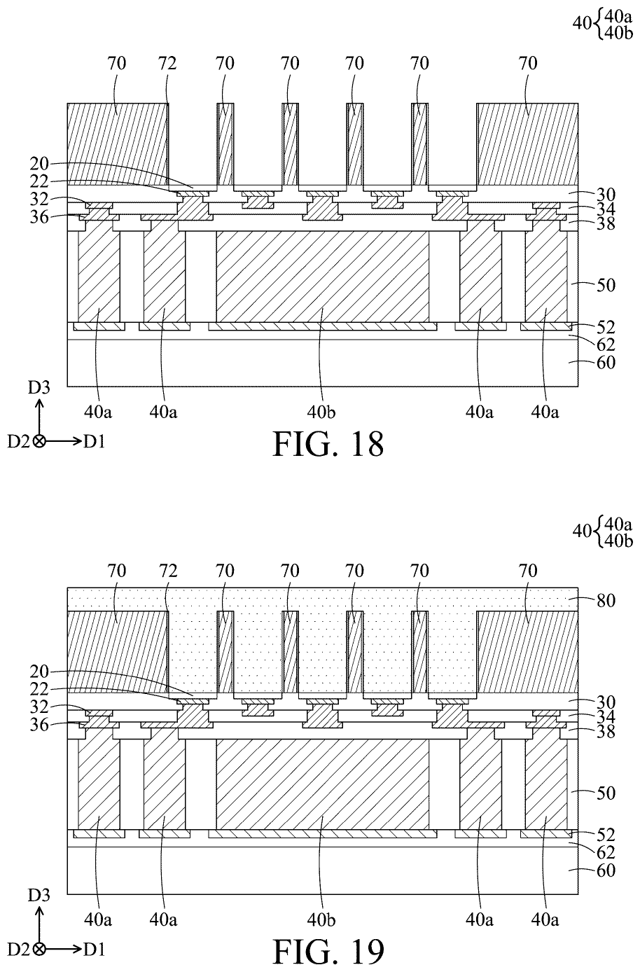

As shown in FIG. 18, in some embodiments, a reflective layer 72 may be formed on the side surface of the metal barrier wall 70. In some embodiments, the reflective layer 72 may be formed by electroplating, chemical vapor deposition, sputtering, atomic layer deposition, another suitable forming process, or a combination thereof, but the present disclosure is not limited thereto. In some embodiments, the reflective layer 72 may expose the light-emitting element 20. In some embodiments, in the third direction D3, the reflective layer 72 may not overlap with the light-emitting element 20. In other words, the light-emitting surface of the light-emitting element 20 will not be blocked by the reflective layer 72 and the metal barrier wall 70.

As shown in FIG. 19, in some embodiments, a color conversion layer 80 may be blanketly formed on the light-emitting element 20, the side surface and the top surface of the reflective layer 72, and the top surface of the metal barrier wall 70.

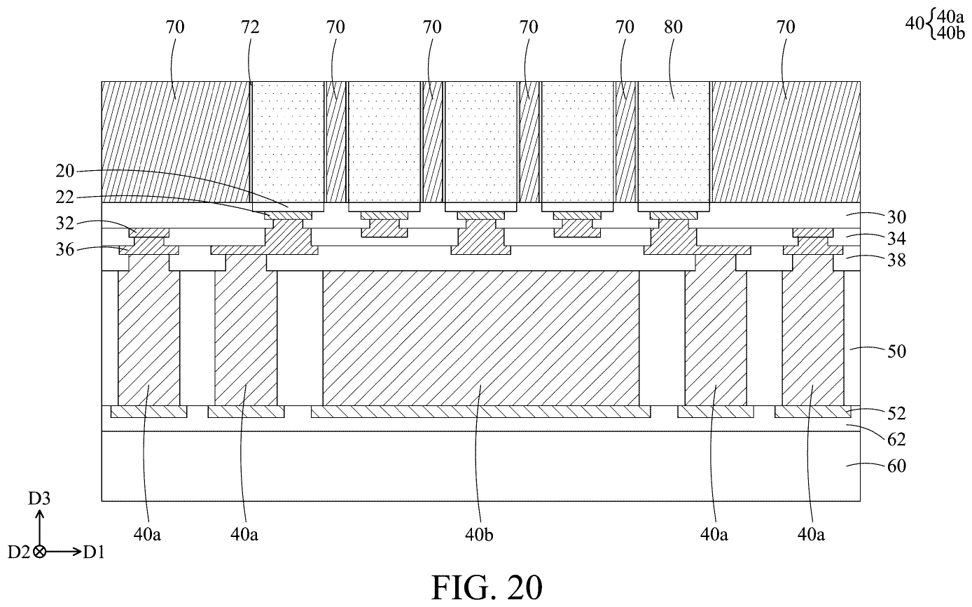

As shown in FIG. 20, in some embodiments, a removal process may be performed to make the top surface of the color conversion layer 80, the top surface of the reflective layer 72, and the top surface of the metal barrier wall 70 to be flush with each other. In some embodiments, the removal process may include a chemical mechanical polishing process, another suitable removal process, or a combination thereof, but the present disclosure is not limited thereto. In some embodiments, the carrier 60 and the second adhesive layer 62 may be further removed. In some embodiments, the carrier 60 and the second adhesive layer 62 may be removed by a removal process corresponding to the second adhesive layer 62. Therefore, the packaging structure 1 shown in FIG. 1 may be obtained.

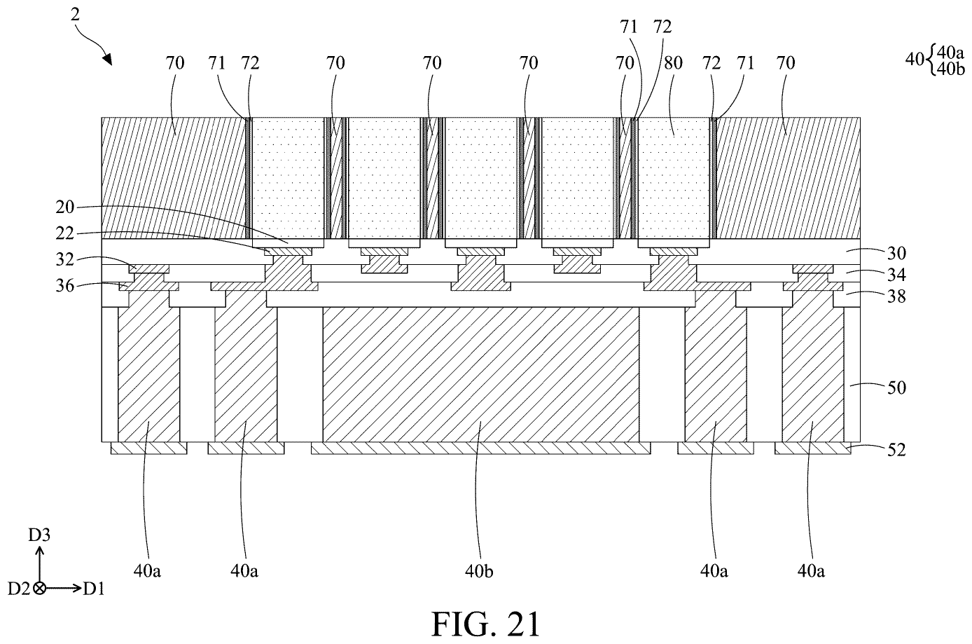

Referring to FIG. 21, it is a schematic cross-sectional view of a packaging structure 2 of some embodiments of the present disclosure. As shown in FIG. 21, in some embodiments, the packaging structure 2 may include a passivation layer 71. In some embodiments, the passivation layer 71 may be disposed on the dielectric structure DS. In some embodiments, the passivation layer 71 may be disposed between the reflective layer 72 and the metal barrier wall 70. In some embodiments, the passivation layer 71 may be used to protect the metal barrier wall 70 to prevent the metal barrier wall 70 from being degraded by the external environment, such as oxidation, sulfurization, or other types of degradation. For example, the passivation layer 71 may serve as an anti-sulfurization layer. In some embodiments, the reflective layer 72 may surround the color conversion layer 80, the passivation layer 71 may surround the reflective layer 72, and the metal barrier wall 70 may surround the passivation layer 71.

In some embodiments, the passivation layer 71 may include metal, oxide, nitride, another suitable passivation material, or a combination thereof, but the present disclosure is not limited thereto. In some embodiments, the reactivity of the material of the passivation layer 71 may be lower than the reactivity of the material of the metal barrier wall 70. In some embodiments, the passivation layer 71 may include metal, and the metal barrier wall 70 may include metal. In some embodiments, the passivation layer 71 may include gold (Au) or nickel (Ni), and the metal barrier wall 70 may include copper (Cu). In some embodiments, continuing with FIG. 17, the passivation layer 71 may be formed on the side surface of the metal barrier wall 70. Then, processes similar to those shown in FIGS. 18 to 20 may be performed to form the packaging structure 2.

In some embodiments, an adaptive headlamp may include packaging structures 1, 2, or a combination thereof, but the present disclosure is not limited thereto. In some embodiments, the adaptive headlamp may include a processor (not shown) and an image capture device (not shown). In some embodiments, the processor may be electrically connected to the packaging structure to perform calculations. In some embodiments, the processor may include a central processing unit (CPU), a multi-core CPU, a graphics processing unit (GPU), the like, or a combination thereof, but the present disclosure is not limited thereto. In some embodiments, the image capture device may include a camera, a video recorder, the like, or a combination thereof, but the present disclosure is not limited thereto. In some embodiments, the image capture device may capture and transmit an image to the processor. In some embodiments, the processor analyzes the captured image to determine whether one or more of the plurality of light-emitting elements 20 in the packaging structure 1, 2 are turned on or turned off. For example, at least one of the plurality of light-emitting elements 20 may be determined to be turned on or turned off, depending on the environment.

Accordingly, the packaging structure disclosed in the present disclosure blocks the light emitted by one of the plurality of light-emitting elements from irradiating another of the plurality of light-emitting elements by disposing the metal barrier wall. Therefore, the metal barrier wall disclosed in the present disclosure may avoid optical cross-talk, thereby improving the light-emitting quality of the packaging structure. For example, the light-emitting element disclosed in the present disclosure may have a large light-emitting angle to improve the light-emitting uniformity of the light-emitting element. At the same time, the metal barrier wall may be used to avoid optical cross-talk between light-emitting elements with a large light-emitting angle. Therefore, the present disclosure may improve light uniformity and/or avoid optical cross-talk.

Furthermore, the packaging structure disclosed herein may include the reflective layer to further reflect unnecessary light and further avoid optical cross-talk. In addition, the packaging structure disclosed herein may include a passivation layer between the metal barrier wall and the reflective layer to improve the reliability of the metal barrier wall. The packaging structure disclosed herein may include the pillar structure, and the pillar structure may include the conductive pillars and the heat dissipation pillar. Therefore, the packaging structure disclosed herein may be electrically connected to an external element via the conductive pillar. The packaging structure disclosed herein may improve the heat dissipation effect via the heat dissipation pillar to improve the light-emitting stability of the light-emitting element. Therefore, the present disclosure may provide an improved packaging structure with high light-emitting quality and an adaptive headlamp including the packaging structure.

In addition, the scope of the present disclosure is not limited to the process, machine, manufacturing, material composition, device, method, and step in the specific embodiments described in the specification. A person of ordinary skill in the art will understand current and future processes, machine, manufacturing, material composition, device, method, and step from the content disclosed in some embodiments of the present disclosure, as long as the current or future processes, machine, manufacturing, material composition, device, method, and step performs substantially the same functions or obtain substantially the same results as the present disclosure. Therefore, the scope of the present disclosure includes the abovementioned process, machine, manufacturing, material composition, device, method, and steps. It is not necessary for any embodiment or claim of the present disclosure to achieve all of the objects, advantages, and/or features disclosed herein.

The foregoing outlines features of several embodiments of the present disclosure, so that a person of ordinary skill in the art may better understand the aspects of the present disclosure. A person of ordinary skill in the art should appreciate that, the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A packaging structure, comprising:
a dielectric structure;
a redistribution structure disposed in the dielectric structure;
a plurality of light-emitting elements disposed on the dielectric structure and electrically connected to the redistribution structure;
a color conversion layer disposed on the plurality of light-emitting elements; and
a metal barrier wall surrounding the color conversion layer.

2. The packaging structure as claimed in claim 1, further comprising:
a reflective layer disposed between the color conversion layer and the metal barrier wall.

3. The packaging structure as claimed in claim 2, wherein the reflective layer surrounds the color conversion layer.

4. The packaging structure as claimed in claim 2, further comprising:
a passivation layer between the reflective layer and the metal barrier wall.

5. The packaging structure as claimed in claim 4, wherein the passivation layer comprises gold (Au) or nickel (Ni).

6. The packaging structure as claimed in claim 5, wherein the metal barrier wall comprises copper (Cu).

7. The packaging structure as claimed in claim 1, further comprising:
a packaging layer, wherein the dielectric structure is disposed between the packaging layer and the metal barrier wall; and
a pillar structure disposed in the packaging layer.

8. The packaging structure as claimed in claim 7, wherein in a top view, the metal barrier wall is in a mesh shape.

9. The packaging structure as claimed in claim 7, wherein an end portion of the packaging layer protrudes toward the pillar structure.

10. The packaging structure as claimed in claim 7, wherein a material of the pillar structure is the same as a material of the metal barrier wall.

11. The packaging structure as claimed in claim 7, wherein a thermal conductivity of the pillar structure is the same as a thermal conductivity of the metal barrier wall.

12. The packaging structure as claimed in claim 7, wherein the pillar structure further comprises:
conductive pillars electrically connecting the redistribution structure and the plurality of light-emitting elements.

13. The packaging structure as claimed in claim 12, wherein the pillar structure further comprises:
a heat dissipation pillar physically separated from the conductive pillars and electrically isolated from the redistribution structure and the plurality of light-emitting elements.

14. The packaging structure as claimed in claim 13, wherein the heat dissipation pillar is located below the plurality of light-emitting elements.

15. The packaging structure as claimed in claim 13, wherein the conductive pillars surround the heat dissipation pillar.

16. The packaging structure as claimed in claim 13, wherein the end portions of the packaging layer protrude toward the conductive pillars and the heat dissipation pillar.

17. The packaging structure as claimed in claim 7, wherein:
the dielectric structure comprises a first dielectric layer, a second dielectric layer, and a third dielectric layer,
the metal barrier wall is in contact with the first dielectric layer,
the packaging layer is in contact with the third dielectric layer, and
the second dielectric layer is disposed between the first dielectric layer and the third dielectric layer.

18. The packaging structure as claimed in claim 17, wherein:
the redistribution structure comprises a first redistribution layer and a second redistribution layer;
the first redistribution layer is disposed between the first dielectric layer and the second dielectric layer; and
the second redistribution layer is disposed on the second dielectric layer.

19. The packaging structure as claimed in claim 7, further comprising:
a plurality of bonding pads electrically connected to the pillar structure.

20. The packaging structure as claimed in claim 1, wherein an end portion of the color conversion layer protrudes toward the metal barrier wall.
